(19) United States
(12) Patent Application Publication
(10) Pub. No.: US 2013/0021010 A1
(43) Pub. Date: Jan. 24, 2013

(54) DIGITAL PULSE WIDTH MODULATION CONTROLLER FOR POWER MANAGEMENT

(71) Applicants: FANG-TA TAI, Tu-Cheng (TW); JEN-FAN SUN, Tu-Cheng (TW); CHEN-HSIANG LIN, Tu-Cheng (TW); CHENG-I LIN, Tu-Cheng (TW)

(72) Inventors: FANG-TA TAI, Tu-Cheng (TW); JEN-FAN SUN, Tu-Cheng (TW); CHEN-HSIANG LIN, Tu-Cheng (TW); CHENG-I LIN, Tu-Cheng (TW)

(73) Assignee: HON HAI PRECISION INDUSTRY CO., LTD., Tu-Cheng (TW)

(21) Appl. No.: 13/347,088

(22) Filed: Jan. 10, 2012

(30) Foreign Application Priority Data
Jul. 21, 2011 (TW) 100125868

(51) Int. Cl. G05F 1/00; H03K 3/017

(52) U.S. Cl. 323/282; 327/172

(57) ABSTRACT

A digital pulse width modulation (PWM) controller is used for controlling the operating voltage of an electrical load and includes a setting module, a storage module and a control module. The setting module generates control parameters corresponding to different preset load currents and load voltages of the electrical load. The storage module stores the control parameters and the prestored load current and load voltage. The control module is in electronic communication with the storage module, and detects current load voltage and current load current of the electrical load, and compares the current load voltage and load current with the prestored load voltage. Thus, the control module can output the control parameters which are necessary to stabilize the operating voltage of the electrical load, by comparison with stored data.

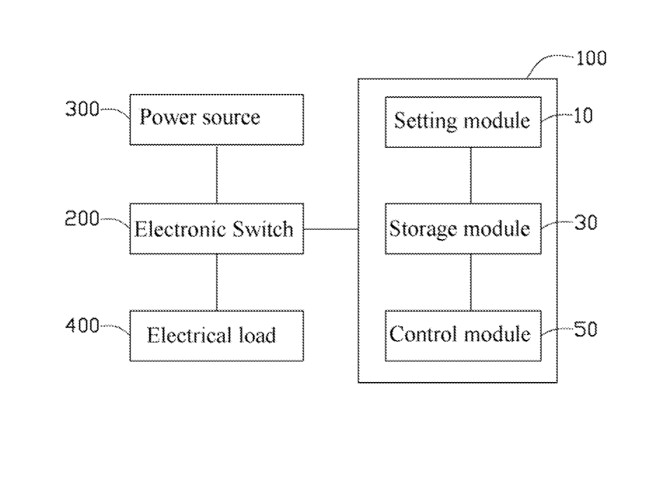

### BACKGROUND

1. Technical field

The disclosure generally relates to pulse width modulation (PWM) controllers, and more particularly to a digital PWM controller.

2. Description of the Related Art

Analog circuits are employed in PWM controllers for direct current (DC) to DC power management. Control parameters of the analog PWM controller such as phase, frequency and drive voltage are determined by the resistance of resistors and the capacitance of capacitors in the analog PWM controller. Once appropriate resistors and capacitors are selected and integrated in the analog PWM controller, the control parameters of the analog PWM controller are fixed and generally non-adjustable. Thus, the control parameters of the analog PWM controller can not be adjusted for different loads, which may reduce the power conversion efficiency.

Therefore, there is room for improvement within the art.

### BRIEF DESCRIPTION OF THE DRAWINGS

Many aspects of a digital pulse width modulation controller can be better understood with reference to the following drawings. The components in the drawings are not necessarily drawn to scale, the emphasis instead being placed upon clearly illustrating the principles of the digital pulse width modulation controller. Moreover, in the drawings, like reference numerals designate corresponding parts throughout the several views. Wherever possible, the same reference numbers are used throughout the drawings to refer to the same or like elements of an embodiment.

The drawing is a schematic functional block view of a digital pulse width modulation controller for power management, according to an exemplary embodiment of the present disclosure.

### DETAILED DESCRIPTION

The drawing is a schematic functional block view of a digital pulse width modulation (PWM) controller 100 for power management, according to an exemplary embodiment of the present disclosure. In this embodiment, the controller 100 is in electronic communication with an electronic switch 200, and the electronic switch 200 is electrically connected to a power source 300 and to an electrical load 400. The controller 100 can turn the electronic switch 200 on or off, thereby governing the power source 300 which provides operating voltage for the electrical load 400 through the electronic switch 200. The electronic switch 200 can be a metal-oxide-semiconductor field-effect transistor (MOSFET), and the power source 300 can be a power supply unit.

In this embodiment, the controller 100 can dynamically output control parameters to the electronic switch 200, and change as required, according to current load voltage and load current of the electrical load 400. Thus a continuously suitable operating voltage for the electrical load 400 from the power source 300 is enabled through the electronic switch 200 according to the control parameters being output and the conversion efficiency of the power source 300 is thereby improved. The control parameters include phase, frequency and/or drive voltage of the PWM signal.

The controller 100 includes a setting module 10, a storage module 30, and a control module 50. The setting module 10, the storage module 30 and the control module 50 are in electronic communication with the electronic switch 200. In this embodiment, the setting module 10 is capable of calculating, monitoring, and adjusting the conversion efficiency of the power source 30 substantially in real time according to load voltage and load current of the electrical load 400 and input voltage and input current from the power source 300. For example, if the input voltage of the electrical load 400 provided by the power source 300 is Vin, the input current of the electrical load 400 is Iin, and the load voltage of the electrical load 400 is Vo (e.g., 3.3V, 5V or 12V), the load current of the electrical load 400 is Io, then the setting module 10 can calculate the conversion efficiency n of the power source 30 by using the equation n=(Vo*Io)/(Vin*Iin).

The setting module 10 can further calculate and create a conversion efficiency table illustrating the relationship between the control parameters and the conversion efficiency of the power source 300. If the load current of the electrical load 400 is 5 A and a frequency is 200 kHz, the corresponding conversion efficiency n is 60%. If the load current is 10 A, and the frequency is 300 kHz, then the corresponding conversion efficiency is 65%.

The storage module 30 is in electronic communication with the setting module 10, and is capable of storing the control parameters, the conversion efficiency table, and other information. The control module 50 is in electronic communication with the storage module 30, and can access and obtain control parameters from the storage module 30. In this embodiment, the control module 50 detects current load current and current load voltage (e.g., 3.3V, 5V or 12V) of the electrical load 400, and compares the current load current and load voltage with the preset quantities in the conversion efficiency table, and searches for an equivalent load current and load voltage in the conversion efficiency table, and transmits control parameters corresponding to the equivalent load current and load voltage to the electronic switch 200. Thus, the current load voltage and the current load current are stored in the storage module 30, and the control module 50 transmits control parameters to the electronic switch 200, the control parameters can vary with the current load voltage and load current of the electrical load 400 to ensure appropriateness and high stability in the load voltage supplied to the electrical load 400.

For example, when the control module 50 detects that the current load current of the electrical load 400 is about 5 A, the frequency corresponding to the current load current is 200 kHz, and the conversion efficiency is 65%. If the current load current of the electrical load 400 is about 10 A, the frequency corresponding to the current load current is 300 kHz, and the conversion efficiency is 65%. Thus, when the load current and the load voltage of the electrical load 400 changes, the controller 100 can provide adjustment and output changeable control parameters to the electronic switch 200 in real time to stabilize the current load voltage and load current.

In use, for example, if the control module 50 detects that the current load current of the electrical load 400 is 5 A, the control module 50 may search the control parameters corresponding to the load current of 5 A in the conversion efficiency table of the storage module 30. The controller 100 then outputs the control parameters which require a frequency of 200 kHz to the electronic switch 200, thereby the power source 300 can provide operating voltages in precise correspondence for the electrical load 400 through the electronic switch 200.

The control module 50 detects the current load voltage of the electrical load 400, and compares the current load voltage with the preset load voltage in the conversion efficiency table to establish a preset load voltage which is equal to or close to the current load voltage, to further establish the control parameters relating to the preset load voltage. For example, when the current load voltage is about 3.32V, the control module 50 then selects a conversion efficiency of 60% and the other control parameters in the conversion efficiency table which correspond to the load voltage of 3.3V which is the closest to the current load voltage of 3.32V. Thus, the controller 100 then can output the necessary control parameters to the electronic switch 200 to stabilize the operating voltage supplied to the electrical load 400.

In summary, in the digital PWM controller 100 of the present disclosure, the control module 50 can detect the current load current and the current load voltage of the electrical load 400 in real time, and obtain the control parameters according to the current load voltage and load current. The controller 100 can then carry out an adjustment almost instantaneously to stabilize the current load voltage of the electrical load 400 by outputting the relevant control parameters to the electrical load 400. Thus, when the load current and/or the load voltage of the electrical load 400 changes, the controller 100 can provide and output the necessary control parameters to the electronic switch 200 in real time to stabilize the operating voltage and load current.

In the present specification and claims, the word “a” or “an” preceding an element does not exclude the presence of a plurality of such elements. Further, the word “comprising” does not exclude the presence of elements or steps other than those listed.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of the exemplary disclosure to the full extent indicated by the broad general meaning of the terms in which the appended claims are expressed.

What is claimed is:

1. A digital pulse width modulation (PWM) controller used for controlling operating voltage of an electrical load, the digital PWM controller comprising:
a setting module creating corresponding control parameters based on different preset load currents and load voltages of the electrical load; and
a control module detecting current load voltage and/or load current of the electrical load, comparing the current load voltage and/or current load current with the preset quantities, and outputting the control parameters corresponding to the current load voltage and/or load current to control the operating voltage of the electrical load.

2. The digital PWM controller as claimed in claim 1, wherein the control module is in electronic communication with an electronic switch, the control module turns on or off the electronic switch according to the control parameters, and the control parameter comprise phase, frequency and drive voltage.

3. The digital PWM controller as claimed in claim 2, wherein the electronic switch is electrically connected to a power source and the electrical load, the power source provides operating voltage for the electrical load through the electronic switch according to the control parameters, and the electronic switch is a metal-oxide-semiconductor field-effect transistor.

4. The digital PWM controller as claimed in claim 3, wherein the setting module is in electronic communication with the electronic switch, and calculates, monitors and adjusts conversion efficiency of the power source substantially in real time according to the current load voltage and the current load current of the electrical load and input voltage and input current from the power source.

5. The digital PWM controller as claimed in claim 4, wherein the setting module calculates and creates a conversion efficiency table illustrating the relationship between the control parameters and the conversion efficiency of the power source.

6. The digital PWM controller as claimed in claim 5, further comprising a storage module in electronic communication with the setting module and the control module, wherein the storage module stores the control parameters, the conversion efficiency table, and other information.

7. The digital PWM controller as claimed in claim 6, wherein the control module detects the current load current and the current load voltage of the electrical load, and compares the current load current and load voltage with the preset load current and load voltage to search for an equivalent load current and load voltage in the conversion efficiency table, and the control module controls the storage module to output the corresponding control parameters to the electronic switch.

8. A digital pulse width modulation (PWM) controller used for controlling operating voltage of an electrical load, the digital PWM controller comprising:
a setting module generating corresponding control parameters according to different prestored load currents and load voltages of the electrical load;
a storage module in electronic communication with the setting module to store the control parameters and the prestored load current and load voltage; and
a control module in electronic communication with the storage module, wherein the control module detects current load voltage and current load current of the electrical load, and compares the current load voltage and load current with the prestored load voltage and load current, and outputs the corresponding control parameters according to the comparison to stabilize the operating voltage supplied to the electrical load.

9. The digital PWM controller as claimed in claim 8, wherein the control module is in electronic communication with an electronic switch, the control module turns on or off the electronic switch according to the control parameters, and the control parameter comprise phase, frequency and drive voltage.

10. The digital PWM controller as claimed in claim 9, wherein the electronic switch is electrically connected to a power source and the electrical load, the power source provides operating voltage for the electrical load through the electronic switch according to the control parameters, and the electronic switch is a metal-oxide-semiconductor field-effect transistor.

11. The digital PWM controller as claimed in claim 10, wherein the setting module is in electronic communication with the electronic switch, and calculates, monitors and adjusts conversion efficiency of the power source substantially in real time according to the current load voltage and the current load current of the electrical load and input voltage and input current from the power source.

12. The digital PWM controller as claimed in claim 11, wherein the setting module calculates and creates a conversion efficiency table that illustrates the relationship between the control parameters and the conversion efficiency of the power source.

13. The digital PWM controller as claimed in claim 6, wherein the control module detects the current load current and load voltage of the electrical load, and compares the current load current and load voltage with the prestored load current and load voltage to obtain an equivalent load current and load voltage in the conversion efficiency table, and the control module controls the storage module to output the corresponding control parameters to the electronic switch.
